(19) United States
(12) Patent Application Publication
(10) Pub. No.: US 2025/0237415 A1
(43) Pub. Date: Jul. 24, 2025

(54) COOLING APPARATUS, ENERGY STORAGE SYSTEM INCLUDING SAME, AND METHOD OF COOLING ENERGY STORAGE SYSTEM

(71) Applicant: Samsung SDI Co., Ltd., Yongin-si (KR)

(72) Inventor: Yusik Hwang, Yongin-si (KR)

(73) Assignee: Samsung SDI Co., Ltd., Yongin-si (KR)

(21) Appl. No.: 18/755,225

(22) Filed: Jun. 26, 2024

(30) Foreign Application Priority Data
Jan. 18, 2024 (KR) 10-2024-0008192

(51) Int. Cl. F25B 21/02

(52) U.S. Cl. CPC F25B 21/02; F25B 2321/0212; F25B 2321/0252

(57) ABSTRACT

Provided are a cooling apparatus, an energy storage system including the same, and a method of cooling an energy storage system using the same. In the cooling apparatus, a cooling water flow device includes a recovery pipe and a discharge pipe through which cooling water is recovered to and discharged from a storage tank. A temperature controller is disposed on the storage tank to control a temperature of the cooling water stored in the storage tank by means of a load current applied thereto. A flow rate controller is disposed on the discharge pipe of the cooling water to control a discharge flow rate of the cooling water by means of a flow rate control current. A cooling controller simultaneously controls the discharge flow rate and a cooling temperature of the cooling water by driving the flow rate controller and the temperature controller in response to a cooling signal.

### CROSS REFERENCE TO RELATED APPLICATION

The present application claims priority to and the benefit under 35 U.S.C. § 119 (a) of Korean Application No. 10-2024-0008192, filed on Jan. 18, 2024, in the Korean Intellectual Property Office, the entire disclosure of which is incorporated by reference herein.

### FIELD

The present disclosure relates to a cooling apparatus, an energy storage system including the same, and a method of cooling an energy storage system using the same. And, more particularly, to a cooling chiller configured to control a cooling temperature and a discharge flow rate together, an energy storage system including the same, and a method of cooling an energy storage system using the same.

### BACKGROUND

Typical energy storage systems respectively have a battery module including an array of a plurality of secondary cells as a unit cell. Such energy storage systems may be categorized into a rack unit including tens to hundreds of unit modules fixed to a single frame, an energy storage container including tens to hundreds of rack units stacked together, and an energy storage building including tens to hundreds of energy storage containers stacked together.

Secondary batteries are structurally prone to overheating and fire due to the reaction heat generated by the activity of the chemical cells. In particular, in energy storage systems, each including a large number of stacked cells, overheating and fire are the most serious causes of system reliability degradation.

Accordingly, various efforts have been made to prevent operational abnormalities and fires caused by overheating in energy storage systems. Control centers of such energy storage systems use fire safety devices to detect abnormal cells having abnormal operating temperatures in advance or, in the event of a fire, to detect gas or smoke and extinguish the fire early by spraying cooling water.

However, even in a case where gas or smoke is detected in advance, it is difficult to take practical preventive measures because a corresponding unit cell is malfunctioning or damaged in a situation where the smoke is generated.

In addition, in cooling apparatuses for energy storage systems of the related art, it is difficult to change an initially set cooling temperature, and no method is provided for rapidly cooling an overheated cell in a case where the overheated cell is detected. Therefore, even in a case where the overheated cell is detected, it is difficult to speed up the cooling of the overheated cell.

Accordingly, there is a growing need for new cooling apparatuses and energy storage systems that may rapidly cool an overheated cell in a case where the overheated cell is found in order to prevent cell failure or damage due to overheated cell.

### SUMMARY

One or more embodiments include a cooling apparatus for rapidly cooling an overheated cell when the overheated cell is found.

One or more embodiments include an energy storage system including the cooling apparatus.

One or more embodiments include a method of cooling the energy storage system using the cooling apparatus.

However, the technical problem to be solved by the present disclosure is not limited to the above problem, and other problems not mentioned herein, and aspects and features of the present disclosure that would address such problems, will be clearly understood by those skilled in the art from the description of the present disclosure below.

A cooling apparatus according to one or more embodiments may include a cooling water flow device including a recovery pipe through which cooling water is recovered to a storage tank and a discharge pipe through which the cooling water is discharged from the storage tank. A temperature controller may be disposed on the storage tank to control a temperature of the cooling water stored in the storage tank based on a load current applied thereto. A flow rate controller disposed on the discharge pipe of the cooling water may control a discharge flow rate of the cooling water based on a flow rate control current. A cooling controller may control the discharge flow rate and a cooling temperature of the cooling water together by driving the flow rate controller and the temperature controller in response to a cooling signal.

According to one or more additional embodiments, the temperature controller may include a cooling plate configured to cover an outer surface of the storage tank. A plurality of thermoelectric devices may each comprise a top portion in contact with a bottom portion of the cooling plate and may cool the cooling water by Peltier effect via the cooling plate. A heat dissipation plate in contact with bottom portions of the plurality of thermoelectric devices may dissipate heat absorbed from the cooling water.

According to one or more additional embodiments, each of the plurality of thermoelectric devices may include a pair of semiconductor elements having different polarities, individual conductors provided as electrodes in contact with the pair of semiconductor elements, respectively, and a bridge conductor in simultaneous contact with the pair of semiconductor elements to be provided as a bridge electrode and in contact with the cooling plate.

According to one or more additional embodiments, the pair of semiconductor elements may include p-type and n-type semiconductors connected in series and include bismuth telluride (Bi2Te3) and/or lead telluride (PbTe).

According to one or more additional embodiments, each of the individual conductors may include a copper plate.

According to one or more additional embodiments, the temperature controller may further include a first power supply to generate a direct current in a switching mode.

According to one or more additional embodiments, the flow rate controller may include an electric flow rate control valve to control the discharge flow rate of the cooling water in proportion to the flow rate control current.

According to one or more additional embodiments, the flow rate controller may include a valve spool including a flow path that may be connected to the discharge pipe in a flow direction of the cooling water, the flow path being selectively connected by means of a connecting hole, and a coupling opening connected to the flow path and extending in a coupling direction different from the flow path. A valve piston may be inserted in and rotatably coupled to the coupling opening, and may move linearly in the coupling direction by rotational movement in the coupling opening, thereby changing an open area of the connecting hole. A drive unit may drive the valve piston, and a second power supply may supply the flow rate control current as a direct current to the drive unit.

According to one or more additional embodiments, the cooling controller may include a temperature setting portion to set a target temperature for the cooling water A first driver may drive the temperature controller so that a recovery temperature of the cooling water is equal to the target temperature. A second driver may drive the flow rate controller to control the discharge flow rate of the cooling water, and a cooling processor may set operating states of the temperature controller and the flow rate controller by comparing a discharge temperature of the cooling water and the target temperature.

According to one or more additional embodiments, the recovery pipe may include a first temperature sensor disposed at an inlet to detect the recovery temperature of the cooling water entering the storage tank. The discharge pipe may include a second temperature sensor disposed at an outlet to detect the discharge temperature of the cooling water discharged from the storage tank.

An energy storage system according to one or more embodiments may include a housing including a flow path through which cooling water flows, an energy storage including a plurality of energy storage cells arranged within the housing to store electrical energy and cooled with the cooling water. A cell control center may detect operating states of the energy storage cells by simultaneous contact therewith and transmit a cooling signal for rapidly cooling a detected overheated cell among the energy storage cells. A cooling apparatus may circulate the cooling water within the housing to cool the energy storage and simultaneously control a cooling temperature and a discharge flow rate of the cooling water in response to the cooling signal.

According to one or more additional embodiments, the housing may include an inlet through which the cooling water enters, an outlet through which the cooling water is discharged, and flow guides configured to guide the cooling water to the energy storage cells.

According to one or more additional embodiments embodiment, the cooling apparatus may include a cooling water flow device including a recovery pipe connected to the outlet to allow cooling water to be recovered to a storage tank therethrough and a discharge pipe connected to the inlet and may allow the cooling water to be discharged from the storage tank to the housing. A temperature controller disposed on the storage tank may control a temperature of the cooling water stored in the storage tank based on a load current applied thereto. A flow rate controller disposed between the discharge pipe and the storage tank may control the discharge flow rate of the cooling water based on a flow rate control current. A cooling controller may control the discharge flow rate and the cooling temperature of the cooling water together by driving the flow rate controller and the temperature controller in response to a cooling signal.

According to one or more additional embodiments, each of the cell control center and the cooling controller may communicate cooling information via wired communication and/or wireless communication.

According to one or more additional embodiments, the cooling controller may include a temperature setting device to set a target temperature. A first driver may drive the temperature controller so that a recovery temperature of the cooling water is equal to the target temperature. A second driver may drive the flow rate controller to control the discharge flow rate of the cooling water, and a cooling processor may control operations of the first driver and the second driver by comparing a discharge temperature of the cooling water and the target temperature.

A method of cooling an energy storage system according to one or more embodiments may include receiving a cooling signal for rapidly cooling localized overheating from a cell control center of energy storage cells cooled with cooling water, driving thermoelectric devices to reduce a temperature of cooling water recovered from a housing to a target temperature for the rapid cooling, controlling a discharge flow rate of the cooling water according to a discharge temperature of the cooling water discharged from the storage tank, and supplying the cooling water to the housing. The cooling temperature and the discharge flow rate of the cooling water may be controlled.

According to one or more additional embodiments, the driving of the thermoelectric devices may include setting the cooling target temperature of the cooling water, detecting a recovery temperature of the cooling water recovered to the storage tank, obtaining a load current capable of removing an amount of dissipation heat between the recovery temperature and the target temperature, and applying the load current as a direct current to the thermoelectric devices.

According to one or more additional embodiments, an intensity of the load current may be controlled by adjusting a switch-on time of a switching mode power supply.

According to one or more additional embodiments, the controlling of the discharge flow rate may include detecting the discharge temperature of the cooling water discharged the storage tank, setting a variation flow rate corresponding to the discharge temperature, generating a flow rate control current corresponding to the variation flow rate, and adjusting an open area of a flow path through which the cooling water flows by applying the flow rate control current to a valve piston.

According to one or more additional embodiments, the flow rate control current may be positively correlated with the discharge temperature so that the flow rate control current is controlled to increase with increases in the discharge temperature.

When localized overheating occurs in an energy storage during operation, the overheated state may be detected in advance, and, according to various embodiments of the cooling apparatus, the energy storage system including the same, and the method of cooling an energy storage system using the same, the cooling apparatus may be controlled in advance to rapidly cool the localized heating, thereby preventing the localized overheating from causing damage, failure, or fire to the energy storage cells.

According to one or more embodiments, the overheated cell may be rapidly cooled by transmitting the localized overheated state in the cooling signal to the cooling apparatus, cooling the cooling water to a target temperature, and supplying the cooling water at an increased flow rate to the energy storage.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 illustrates a configuration of a cooling apparatus according to some embodiments;

FIG. 2 illustrates a perspective view showing an exemplary configuration of the temperature controller shown in FIG. 1;

FIG. 3 illustrates a cross-sectional view showing an exemplary embodiment of the thermoelectric device provided in the temperature controller shown in FIG. 2;

FIG. 4 illustrates a configuration of the flow rate controller shown in FIG. 1 according to some embodiments;

FIGS. 5A, 5B, and 5C are views illustrating a flow rate control process performed by the flow rate controller shown in FIG. 4;

FIG. 6 illustrates a configuration of an energy storage system including the cooling apparatus shown in FIG. 1 according to some embodiments;

FIG. 7 illustrates a flowchart showing a method of cooling an energy storage using the cooling apparatus shown in FIG. 1 according to some embodiments;

FIG. 8 illustrates a flowchart showing a method of driving the thermoelectric device according to some embodiments; and

FIG. 9 illustrates a flowchart showing a method of controlling a discharge flow rate according to some embodiments.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

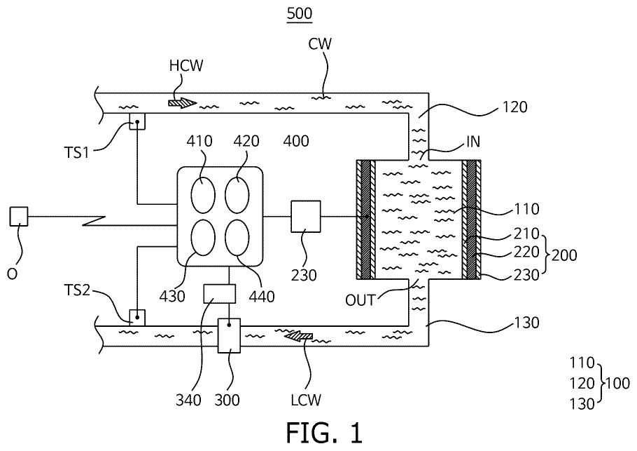

FIG. 1 illustrates a configuration of a cooling apparatus according to some embodiments. A chiller for cooling an energy storage system including a secondary battery is described, but this is illustrative. It should be appreciated that modifications and equivalents of the cooling apparatus are within the spirit and scope of the present disclosure. The various embodiments pertain to a cooling apparatus capable of rapidly cooling an overheated unit and the adjacent units by reducing a temperature of cooling water upon detection of the overheated unit in an object to be cooled (i.e., a cooling object).

Referring to FIG. 1, a cooling apparatus 500 according to some embodiments may include a cooling water flow device 100 configured to circulate cooling water CW passing through a cooling object O, a temperature controller 200 configured to selectively control the temperature of the cooling water CW, a flow rate controller 300 configured to control a discharge flow rate of the cooling water CW, and a cooling controller 400 configured to control the cooling temperature and the discharge flow rate of the cooling water CW together.

In an exemplary embodiment, the cooling water flow device 100 may include a storage tank 110 storing the cooling water CW, a recovery pipe 120 through which the cooling water CW is recovered to the storage tank 110, and a discharge pipe 130 through which the cooling water CW is discharged from the storage tank 110.

The storage tank 110 may be implemented as an open integrated three-dimensional (3D) structure, including an inlet IN and an outlet OUT, and may include a combination of metal plates of high thermal conductivity metals, such as aluminum (Al) or copper (Cu), to facilitate heat transfer with respect to a thermoelectric device 220 described later.

The cooling water CW that has cooled a cooling object O is converted to hot cooling water HCW having a relatively high temperature. The hot cooling water HCW is recovered to the storage tank 110 through the recovery pipe 120 connecting the cooling object O and the inlet IN.

Accordingly, the recovery pipe 120 may have various shapes and be made of various materials, whereby the cooling object O may be connected to the storage tank 110 and the cooling water CW may be recovered without loss of flow.

The cooling water CW sufficiently cooled in the storage tank 110 is discharged from the outlet OUT. The discharge pipe 130 is connected to the outlet OUT, whereby the cooled cooling water CW flows to the cooling object O through the discharge pipe 130. The recovery pipe 120 and the discharge pipe 130 may have substantially the same composition and shape.

The temperature controller 200 may be disposed on the storage tank 110 to reduce the temperature of the recovered cooling water CW. That is, the temperature controller 200 may reduce the cooling temperature of the cooling water CW to rapidly cool an overheated region created inside the cooling object O as desired.

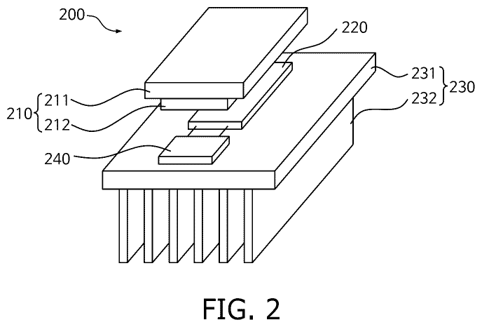

FIG. 2 illustrates a perspective view showing an exemplary embodiment of the temperature controller 200 shown in FIG. 1.

Referring to FIG. 2, the temperature controller 200 according to some embodiments of the present disclosure may include cooling plates 210 covering outer surfaces of the storage tank 110, a plurality of thermoelectric devices 220 having the top portions in contact with the bottom portions of the cooling plates 210 and configured to cool the cooling water CW by the Peltier effect by cooling the cooling plates 210, and a heat dissipation plate 230 in contact with the bottom portions of the thermoelectric devices 220 to dissipate heat absorbed from the cooling water CW.

The cooling plates 210 are disposed to cover the side surfaces of the storage tank 110, thereby serving as heat sink plates to absorb heat in response to the operation of the thermoelectric devices 220. Consequently, heat may be extracted from the cooling water CW stored in the storage tank 110 through the sidewall of the storage tank 110 in contact with the cooling plates 210, thereby reducing the temperature.

That is, the cooling water CW stored in the storage tank 110 may be cooled to a predetermined cooling temperature by means of a load current applied to the thermoelectric device 220.

Accordingly, the cooling plates 210 may be made of various materials and have various shapes, whereby the cooling plates 210 may correspond to the outer wall shape of the storage tank 110 while having a thermal conductivity to exchange heat sufficiently with the stored cooling water CW through the sidewall of the storage tank 110.

In the exemplary embodiment shown in FIG. 2, the storage tank 110 has a hexahedral shape consisting of six plates, and the cooling plates 210 are flat plates covering the front surfaces of the four sidewalls. Accordingly, the cooling plates 210 are configured to cover the four sidewalls of the storage tank 110 having the inlet IN and the outlet OUT, excluding the cover and the bottom. In the exemplary embodiment of FIG. 2, the cooling plates 210 may be implemented as aluminum plates or copper plates having excellent thermal conductivity.

The thermoelectric device 220 may be configured to cause the cooling plates 210 to act as a heat sink by means of an applied load current.

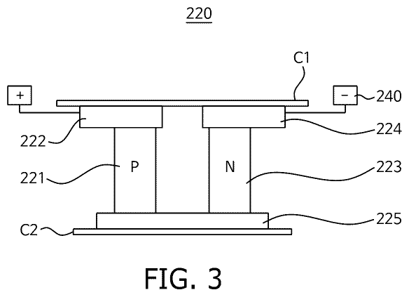

FIG. 3 illustrates a cross-sectional view showing an exemplary thermoelectric device 220 provided in the temperature controller shown in FIG. 2.

Referring to FIG. 3, the thermoelectric device 220 may include a pair of semiconductor elements 221 and 223 having different polarities, individual conductors 222 and 224 provided as electrodes in contact with the semiconductor elements 221 and 223, respectively, and a bridge conductor 225 in simultaneous contact with the semiconductor elements 221 and 223 to be provided as a bridge electrode and in contact with the cooling plates 210.

The pair of semiconductor elements 221 and 223 are implemented using p-type and n-type semiconductors connected in series and including one of bismuth telluride (Bi2Te3) and lead telluride (PbTe).

The first semiconductor element 221 is configured such that one end thereof is in contact with the first individual conductor 222, and the second semiconductor element 223 is configured such that one end thereof is in contact with the second individual conductor 224. The bridge conductor 225 is in contact with both the other ends of the first and second semiconductor elements 221 and 223.

A first power supply 240 applies a DC load current to the first and second individual conductors 222 and 224, and the first and second semiconductor elements 221 and 223, the conductors 222 and 224, and the bridge conductor 225 form a single electronic circuit.

For example, each of the individual conductors 222 and 224 and the bridge conductor 225 may be made of a low resistance metal such as, for example, copper, aluminum, titanium, or tantalum.

Accordingly, the pair of semiconductor elements 221 and 223 may form a single electronic circuit in which the semiconductor elements 221 and 223 are connected to each other in series by the individual conductors 222 and 224 and the single bridge conductor 225. In this manner, the semiconductor elements 221 and 223 form a unit Peltier element of the thermoelectric device 220.

The thermoelectric device 220 is configured such that a plurality of unit Peltier elements as shown in FIG. 3 are arranged in the form of a matrix and connected to each other in series to perform a single operation in response to the power supply 240.

In the present embodiment, the bridge conductor 225 may be configured to be in contact with the cooling plates 210, and the individual conductors 222 and 224 may be configured to be in contact with the heat dissipation plate 230.

The bridge conductor 225 has a larger surface area than the individual conductors 222 and 224, and thus may perform a more efficient heat absorption process in the cooling plates 210.

However, the exemplary arrangement is illustrative, and it should be appreciated that the cooling plates 210 may also be connected to individual conductors 222 and 224.

As shown in FIG. 3, in an exemplary case where the first semiconductor element 221 is implemented using a p-type semiconductor element and the second semiconductor element 223 is implemented using an n-type semiconductor element, the positive electrode terminal of the power supply 240 is connected to the first individual conductor 222 and the negative electrode terminal of the power supply 240 is connected to the second individual conductor 224.

Accordingly, in the thermoelectric device 220, the bridge conductor 225 is implemented as a heat absorption electrode, and the cooling plates 210 in contact with the bridge conductor 225 perform a cooling function. In addition, the individual conductors 222 and 224 may be implemented as heat generating electrodes, and the heat dissipation plate 230 may be configured to be in contact with the individual conductors 222 and 224 to dissipate heat transferred from the individual conductors 222 and 224.

Particularly, a second insulating film C2 may be disposed between the cooling plates 210 and the bridge conductor 225 and a first insulating film C1 may be disposed between the heat dissipation plate 230 and the individual conductors 222 and 224 to insulate the thermoelectric device 220 from the surrounding environment. The first insulating film C1 and the second insulating film C2 may be made of ceramic to perform sufficient heat transfer while providing electrical insulation.

The first power supply 240 may supply the thermoelectric device 220 with DC current. The first power supply 240 may generate DC pulses from an input signal applied from an external AC power source or a battery power source by splitting the input signal into on and off components in a switching mode method. Accordingly, an external power input may be converted to pulsed DC signals by the first power supply 240. That is, the first power supply 240 may be implemented as a switching mode power supply (SMPS).

The magnitude of the DC pulse signal may increase in proportion to the switch-on time. Therefore, in a case where a large load current is desired due to the large amount of heat dissipated from the thermoelectric device 220, the load current applied to the thermoelectric device 220 may simply be increased by adjusting the switch-on time.

Accordingly, the temperature controller 200 as described with reference to FIG. 2 causes the external power for driving the temperature controller 200 to be converted to a DC load current pulsed by the first power supply 240 and then applied to the thermoelectric device 220.

In particular, the magnitude of the load current applied to the thermoelectric device 220 may be adjusted simply by adjusting the switch-on time of the first power supply 240, so that the cooling temperature of the cooling water CW may be rapidly reduced in a simple manner. Accordingly, the cooling temperature of the cooling water CW may be rapidly and simply controlled as desired by the cooling object O.

Returning to FIG. 1, the flow rate controller 300 may be disposed on the discharge pipe 130, through which the cooling water CW is discharged to the cooling object O, to control the discharge flow rate of the cooling water by means of a flow rate control current.

For example, the flow rate controller 300 may include an electric flow rate control valve to control the discharge flow rate of the cooling water CW in proportion to the flow rate control current.

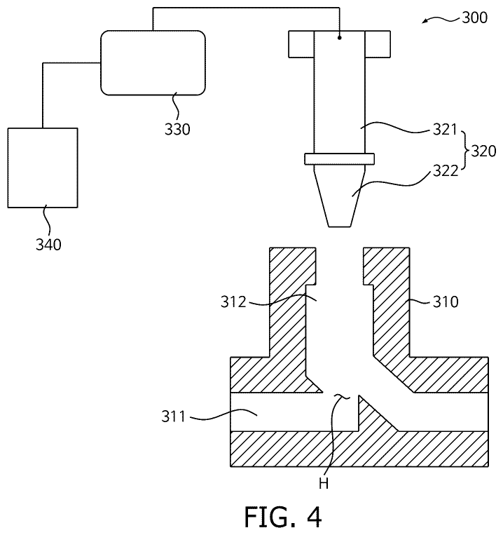

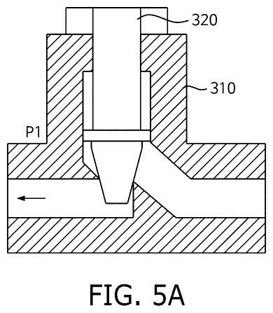

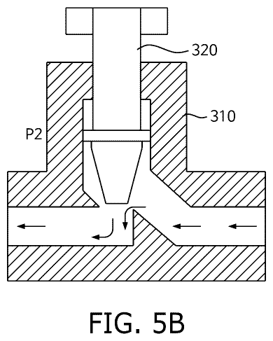

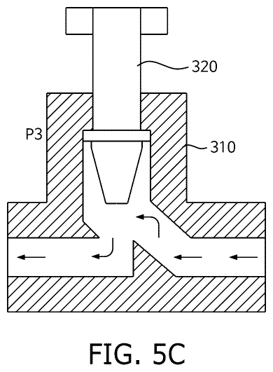

FIG. 4 illustrates an exemplary configuration of the flow rate controller 300 shown in FIG. 1 according to some, and FIGS. 5A to 5C are views illustrating a flow rate control process performed by the flow rate controller 300 shown in FIG. 4.

For example, the flow rate controller 300 may include a valve spool 310, a valve piston 320, a drive unit 330, and a second power supply 340.

The valve spool 310 may include a flow path 311 connected to the discharge pipe 130 in the flow direction of the cooling water CW, the flow path 311 being selectively connected by means of a connecting hole H, and a coupling opening 312 connected to the flow path 311 and extending in a coupling direction different from the flow path 311.

The valve spool 310 may be connected to an intermediate portion of the discharge pipe 130 to change the direction of the cooling water CW discharged from the discharge pipe 130 to flow through the flow path 311, and be selectively coupled to the valve piston 320 at an intermediate portion of the flow path 311 to control the flow rate of the cooling water CW.

The connecting hole H is provided in the intermediate portion of the flow path 311, and the coupling opening 312 configured to receive the valve piston 320 is provided above the connecting hole H. The coupling opening 312 is connected to the outside through an upper portion of the valve spool 310. Accordingly, the flow path 311 and the coupling opening 312 are connected to each other through the connecting hole H, and the flow path 311 communicates with the outside through the coupling opening 312.

The valve piston 320 may be inserted in and rotatably coupled to the coupling opening 312. For example, the valve piston 320 may mesh with the valve spool 310 by means of threads provided on the outer surface of the valve piston 320 and the inner surface of the valve spool 310. Accordingly, the valve piston 320 may move linearly in the coupling direction of the valve piston 320 while rotating on the threads.

That is, the valve piston 320 may be rotatably coupled to the coupling opening 312 by mesh engagement to move linearly in the coupling direction. Accordingly, the valve piston 320 may be disposed to move towards or away from the connecting hole H by the linear movement in the coupling direction to control the degree of opening of the flow path 311.

The valve piston 320 may include a body 321 and a needle valve 322 coupled to one end of the body 321. The body 321 is provided as a base for the needle valve 322, and a sealing means 323 such as an O-ring is disposed between the body 321 and the needle valve 322 to prevent the cooling water CW from leaking from the flow path 311 to the coupling opening 312.

As shown in FIG. 5A, in a case where the valve piston 320 coupled to the coupling opening 312 moves downwards and is positioned at a first position P1, the needle valve 322 completely shuts off the connecting hole H to stop flow of the cooling water CW. Consequently, the flow path 311 is completely blocked, and the flow of the cooling water CW is stopped.

As shown in FIG. 5B, in a case where the valve piston 320 is moved upwards to a second position P2 in response to rotation, the connecting hole H is partially opened, and the cooling water CW flows through the flow path 311 in an amount corresponding to the open area of the connecting hole H. That is, the discharge amount of the cooling water CW may be controlled according to the open area of the flow path 311 by partially opening the flow path 311.

As shown in FIG. 5C, in a case where the valve piston 320 is moved upwards to a third position P3, i.e., the uppermost position, in response to rotation, the needle valve 322 is completely removed from the connecting hole H, and the cooling water CW may be discharged at the maximum flow rate. Consequently, the flow path is fully opened, and the cooling water CW may be discharged at the maximum flow rate.

The valve piston 320 is configured to continuously move from the first position P1 to the third position P3, and the degree of opening of the flow path 311 may be controlled between the closing and the opening according to the position of the needle valve 322 to control the flow rate of the cooling water CW. Accordingly, the flow rate of the cooling water CW may be controlled between the minimum flow rate and the maximum flow rate.

The valve piston 320 may be rotated in the coupling opening 312 by the drive unit 330 and the second power supply 340 shown in FIG. 4.

For example, the drive unit 330 may include a stepping motor. The body 321 is fixed to the stepping motor, and thus may be moved up or down along the threads. Consequently, the needle valve 322 may also be coupled to or decoupled from the connecting hole H.

The second power supply 340 may apply a flow control current to the drive unit 330. Like the first power supply 240, the second power supply 340 may generate a DC flow rate control current by converting an AC signal to a DC signal in the switching mode. Like the first power supply 240, the intensity of the flow rate control current may be easily changed by adjusting the switch-on time.

The stepper motor is driven by the DC flow rate control current, and the displacement of the valve piston 320 is determined in proportion to the intensity of the flow rate control current. Because the degree of opening of the connecting hole H is determined by the displacement of the valve piston 320, the discharge flow rate of the cooling water CW may be simply controlled by adjusting the intensity of the flow rate control current.

Accordingly, in a case where the cooling object O is partially overheated, a proactive response on the overheated cell of the cooling object O may be rapidly performed by not only rapidly cooling the cooling water CW but also immediately changing the discharge flow rate of the cooling water CW.

Returning to FIG. 1, in an exemplary embodiment, the cooling controller 400 may drive the temperature controller 200 and the flow rate controller 300 in response to a cooling signal transmitted from the cooling object O. Accordingly, the discharge flow rate and the cooling temperature of the cooling water CW may be controlled simultaneously.

For example, the cooling controller 400 may include a cooling processor 410, a temperature setting portion 420, a first driver 430, and a second driver 440.

The cooling processor 410 may drive the cooling apparatus 500 to control all components of the cooling apparatus 500 to rapidly cool the overheated cell in the cooling object O.

For example, the cooling processor 410 may analyze information about the overheated cell in the cooling object O and the overheated state by receiving the cooling signal transmitted from the cooling object O. The cooling processor 410 may generate a cooling temperature and a discharge flow rate of the cooling water CW for rapidly cooling the overheated cell. Accordingly, the cooling processor 410 may include a communication module to receive the cooling signal from the cooling object O and a signal processor to process the cooling signal.

The communication module may include a wired communication module, such as a modem, and a wireless communication module, such as a wireless communication chip.

In response to receiving the cooling signal, the cooling processor 410 generates a warning signal, such as an alarm signal, and extracts the cooling temperature for cooling the overheated cell.

The temperature setting portion 420 is set to a rapid cooling temperature of the cooling water CW for rapid cooling of the overheated cell in an emergency. The temperature setting portion 420 may include an arithmetic logic unit configured to detect the overheated temperature from the cooling signal to computationally determine a cooling target temperature of the cooling water CW necessary for the rapid cooling of the overheated cell.

In another example, the temperature setting portion 420 may review the situation of the cooling object O based on the warning signal, and the target temperature of the cooling water CW may be any temperature set by a user. Accordingly, the temperature setting portion 420 may further include a user interface for the user to directly set the target temperature.

In response to receiving the target temperature from the temperature setting portion 420, the cooling processor 410 drives the first driver 430 and the second driver 440 to execute a rapid cooling logic of detecting an optimum temperature and an optimum flow rate of the cooling water CW for the rapid cooling of the overheated cell of the cooling object O.

In response to the cooling processor 410, the first driver 430 drives the temperature controller 200 according to the rapid cooling logic so that a recovery temperature of the cooling water CW is equal to the target temperature.

First, the first driver 430 detects the recovery temperature of the cooling water CW recovered to the storage tank 110 from the cooling object O by using a first sensor (i.e., a temperature sensor) TS1 disposed on the recovery pipe 120.

Because the cooling water CW recovered through the recovery pipe 120 has a relatively high temperature after cooling the inside of the cooling object O, the cooling water CW entering the cooling apparatus 500 is hot cooling water HCW flowing at a relatively high temperature.

The first driver 430 detects the recovery temperature of the hot cooling water HCW, obtains the target temperature of the cooling water CW from the temperature setting portion 420, and generates a load current with respect to the thermoelectric device 220 to dissipate an amount of heat corresponding to the difference between the recovery temperature and the target temperature.

The DC load current corresponding to the amount of heat to be dissipated from the cooling water CW is obtained according to the characteristics of the thermoelectric device 220 and the characteristics of the cooling water CW. The load current is applied to the thermoelectric device 220 through the first power supply 240.

Accordingly, the recovery temperature of the hot cooling water HCW is cooled by the thermoelectric device 220 to low temperature cooling water LCW having the target temperature.

The cooling processor 410 may drive the temperature controller 200 and the flow rate controller 300 together to rapidly perform the rapid cooling of the overheated cell of the cooling object O.

In response to the rapid cooling logic executed by the cooling processor 410, the second driver 440 detects a discharge temperature of the low temperature cooling water LCW discharged from the storage tank 110 by using a second sensor TS2 disposed on the discharge pipe 130.

The cooling water CW discharged from the discharge pipe 130 is cooled by the thermoelectric device 220 to be converted to the low temperature cooling water LCW having a relatively low temperature and supplied to the cooling object O.

In a case where there is a significant temperature difference between the detected discharge temperature and the target temperature, a discharge flow rate of the low temperature cooling water LCW is increased to rapidly perform the cooling of the cooling object O.

In a transient state where the hot cooling water HCW having the recovery temperature is caused to reach the target temperature by the thermoelectric device 220, the temperature of the cooling water CW is set to be lower than the recovery temperature but higher than the target temperature. Therefore, the second driver 440 may control the flow rate controller 300 to increase the flow rate of the cooling water CW discharged from the discharge pipe 130.

In the present embodiment, the flow rate controller includes the proportional needle valve 322 configured to control the discharge flow rate in proportion to the intensity of the DC flow rate control current, and thus may simply control the discharge flow rate of the low temperature cooling water LCW by adjusting the flow rate control current supplied by the second power supply 340.

The second driver 440 may periodically detect the temperature difference between the discharge temperature and the target temperature and adjust the intensity of the flow rate control current in real time in response to the temperature difference. Consequently, the discharge flow rate of the low temperature cooling water LCW may be automatically controlled in conjunction with the temperature difference between the discharge temperature and the target temperature.

Accordingly, in response to the cooling signal, the cooling water CW set to the target temperature, at which the cooling object O may be cooled rapidly, may be supplied at a predetermined flow rate to rapidly cool the overheated cell.

According to the cooling apparatus 500 as described above, the cooling processor 410 may drive the first and second drivers 430 and 440 in response to the cooling signal for the cooling object O to respectively and simultaneously drive the temperature controller 200 and the flow rate controller 300. The overheated cell may be cooled rapidly by supplying the predetermined flow rate of the cooling water CW set to the target temperature at which the cooling object O may be cooled rapidly.

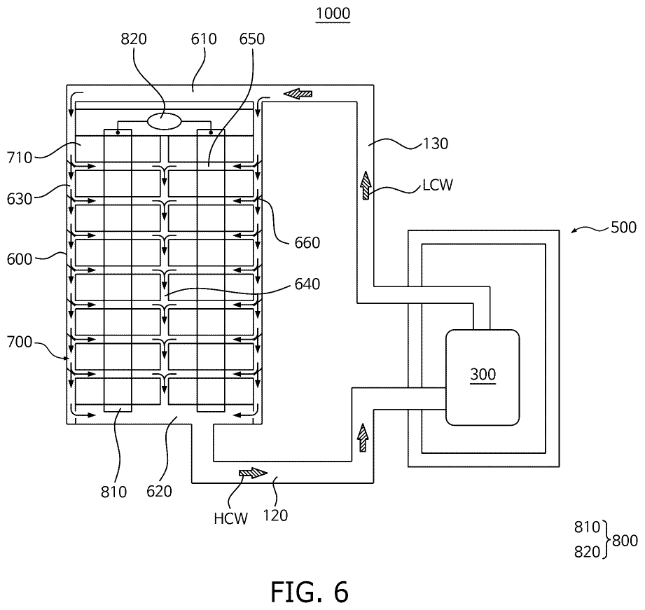

FIG. 6 illustrates the configuration of an energy storage system 1000 including an exemplary cooling object O coupled to the cooling apparatus 500 shown in FIG. 1 according to some embodiments.

Referring to FIG. 6, the energy storage system 1000 may include a housing 600, an energy storage 700 (the exemplary cooling object O) including a plurality of energy storage cells 710, a cell control center 800, and the cooling apparatus 500 configured to supply the cooling water CW to cool the energy storage 700.

The housing 600 may be a three-dimensional structure including a receiving frame (not shown) configured to house the energy storage 700. The three-dimensional structure has defined therein a cooling path through which the supplied cooling water CW may flow.

The housing 600 may include a wall of a sufficient strength to protect the energy storage cells 710 housed therein from external impacts or corrosion. The receiving frame may be partitioned to correspond to the size of the energy storage cells 710, and the internal space of the housing 600, excluding the receiving frame, may be provided as the cooling path through which the cooling water CW flows.

An inlet 610 may be provided on the top portion of the housing 600, allowing the low temperature cooling water LCW having a relatively low temperature to enter the housing 600 therethrough. An outlet 620 may be provided on the bottom portion opposite the top portion, allowing the hot cooling water HCW having a relatively high temperature to be discharged from the housing 600 therethrough. The cooling water CW entering through the inlet 610 absorbs heat from the energy storage cells 710 while flowing through the cooling path inside the housing 600 to be converted to the hot cooling water HCW having a relatively high temperature, which is then discharged from the housing 600.

The hot cooling water HCW discharged from the housing 600 is recovered to the cooling apparatus 500 and cooled by the temperature controller 200 to be reconverted to the low temperature cooling water LCW, which is then supplied to the inlet 610 of the housing 600. Accordingly, the cooling cycle of the cooling water CW for cooling the energy storage cells 710 arranged within the housing 600 is completed.

The energy storage 700 includes a plurality of energy storage cells 710 respectively arranged in the receiving frame within the housing 600. Accordingly, the energy storage cells 710 are arranged in the form of matrix including a plurality of cell columns and a plurality of cell rows.

For example, each of the energy storage cells 710 may be implemented as a secondary battery module including a plurality of secondary batteries that may be charged and discharged. That is, each of the energy storage cells 710 may be implemented as a battery module including a plurality of secondary batteries, and each of the energy storage cells 710 provided in the housing 600 may be implemented as a battery pack including plurality of battery modules.

In the present embodiment, each of the energy storage cells 710 may include lithium ion batteries. However, the exemplary embodiment is not intended to be limiting, and each of the energy storage cells 710 may be implemented as a variety of batteries that may be reversibly charged and discharged.

In the present embodiment, the energy storage cells 710 include a pair of adjacent cell columns extending in the bottom-to-top direction within the housing 600, and a space between the cell columns forms a cooling path through which the cooling water CW flows.

Accordingly, the inside of the housing 600 may include side paths 630 disposed adjacent to the wall of the housing 600 and communicating with the inlet 610 and the outlet 620 and a central path 640 disposed between the adjacent cell columns and communicating with the inlet 610 and the outlet 620.

In addition, a plurality of horizontal paths 650 connecting the side paths 630 and the central path 640 are disposed along the cell rows of adjacent energy storage cells 710 of the respective cell columns. Accordingly, the horizontal paths 650 are disposed below the cell rows, respectively, allowing the cell rows to perform heat exchange with the cooling water CW flowing therebelow so as to dissipate driving heat of the energy storage cells 710.

Flow guides 660 may be disposed between the horizontal paths 650 and the side paths 630 to guide portions of the cooling water CW to the horizontal paths 650. For example, each of the flow guides 660 is implemented as a plate having a guide surface facing in the flow direction of the cooling water CW, and the guide surface is inclined toward the corresponding horizontal path 650.

Accordingly, portions of the cooling water CW flowing through the side paths 630 are guided by the flow guides 660 toward the horizontal paths 650, and the remaining portions of the cooling water CW flow downwards. In this case, the shapes or operations of the flow guides 660 may be controlled to guide equal flow rates of the cooling water CW to the respective horizontal paths 650.

Accordingly, the energy storage 700 may be cooled with the cooling water CW flowing through the side paths 630, the central path 640, and the horizontal paths 650 to dissipate driving heat from the respective energy storage cells 710.

The cell control center 800 may be disposed above the energy storage cells 710 to detect the driving state of the energy storage 700 and control the operation of the energy storage 700.

The cell control center 800 may include a busbar holder 810, including a plurality of busbars connected to the energy storage cells 710, and a battery control module 820 disposed on the busbar holder 810 and configured to detect the driving state of each of the energy storage cells 710.

For example, the busbar holder 810 may be implemented as a printed circuit board, and the battery control module 820 may be implemented as a control device disposed on the printed circuit board.

While the energy storage 700 is operating, the battery control module 820 may detect the operating state of each of the energy storage cells 710 in real time. Herein, in a case where a specific one of the energy storage cells 710 becomes an overheated cell due to overheating and increased temperature, the battery control module 820 generates a cooling signal to request the cooling apparatus 500 to perform a rapid cooling operation on the overheated cell.

In this case, the battery control module 820 may include a wired and/or wireless communication means to transmit the cooling signal.

The cooling signal is transmitted to the cooling apparatus 500 together with information about the overheated cell. The cooling signal is received by the cooling processor 410 of the cooling apparatus 500, allowing the rapid cooling logic to be executed to rapidly cool the overheated cell.

The cooling apparatus 500 may supply the cooling water CW to the housing 600 to enable cooling on the energy storage 700 and, in a case where an overheated cell occurs, may control the temperature and flow rate of the cooling water CW together to rapidly cool the energy storage 700.

The cooling apparatus 500 may include the cooling water flow device 100 including the recovery pipe 120 connected to the outlet 620 to recover the cooling water CW to the storage tank 110 and the discharge pipe 130 connected to the inlet 610 to discharge the cooling water CW from the storage tank 110 to the housing 600, the temperature controller 200 disposed on the storage tank 110 to control the temperature of the cooling water CW stored in the storage tank 110 in response to a load current applied thereto, the flow rate controller 300 disposed between the discharge pipe 130 and the storage tank 110 to control the discharge flow rate of the cooling water CW in response to a flow rate control current, and the cooling controller 400 configured to drive the flow rate controller 300 and the temperature controller 200 in response to the cooling signal to simultaneously control the discharge flow rate and the cooling temperature.

In this case, the cooling controller 400 may include a wired and/or wireless communication module to receive the cooling signal from the battery control module 820.

In the present embodiment, the cooling apparatus 500 has substantially the same configuration as the cooling apparatus 500 described with reference to FIGS. 1 to 5. Accordingly, a further detailed description of the cooling apparatus 500 is omitted.

According to the energy storage system 1000 as described above, in a case where the energy storage 700 has an overheated cell, a rapid cooling signal for the overheated cell may be transmitted to the cooling apparatus 500 to control the cooling temperature and the discharge flow rate of the cooling water CW supplied to the energy storage 700 before heat transfer from the overheated cell to the surrounding cells and resultant cell damage or fire.

Accordingly, before damage or fire to the energy storage 700 is caused by an overheated cell, the overheated cell may be cooled rapidly to prevent damage or destruction of the energy storage system 1000.

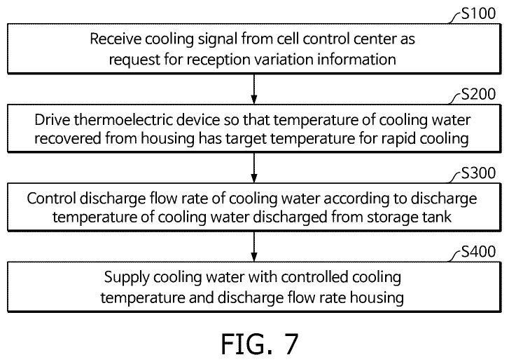

FIG. 7 illustrates a flowchart showing a method of cooling an energy storage using the cooling apparatus shown in FIG. 1 according to some embodiments.

Referring to FIG. 7, a cooling signal for rapid cooling of localized overheating of the energy storage 700 is received from the cell control center 800 (step S100).

In response to the operation of the energy storage system 1000, the cooling apparatus 500 supplies the cooling water CW having a set temperature to the housing 600 to cool the energy storage 700. Consequently, driving heat generated by the energy storage cells 710 operating in the normal operating range is dissipated by the cooling water CW.

Herein, in a case where a localized portion of the energy storage cells 710, i.e., at least one energy storage cell, is overheated, the cell control center 800 generates the cooling signal by detecting the position and state of the overheated cell.

The cooling signal is to indicate the occurrence of an overheated cell. This indicates a condition in which it is desired to rapidly cool the localized overheating of the energy storage 700 before heat transfer from the overheated cell to an adjacent cell occurs. Consequently, in response to the generation of the cooling signal, the cooling signal is transmitted to the cooling processor 410 of the cooling apparatus 500 and a warning device, such as an alarm, is operated.

The cooling signal may be generated as a wired signal or a wireless signal, and may be received by the communication module of the cooling processor 410.

Thereafter, the cooling processor 410 controls the temperature controller 200 and the flow rate controller 300 to operate the cooling apparatus 500 according to the rapid cooling logic.

First, the thermoelectric device 220 is driven so that the temperature of the cooling water CW recovered from the housing 600 has a target temperature for the rapid cooling (step S200).

For example, a temperature difference between a recovery temperature detected by the first sensor TS1 and the target temperature is determined and a load current capable of dissipating an amount of heat corresponding to the temperature difference is obtained. Subsequently, the cooling water CW may be cooled to the target temperature by using the cooling plates 210 by applying the load current to the thermoelectric device 220 through the first power supply 240.

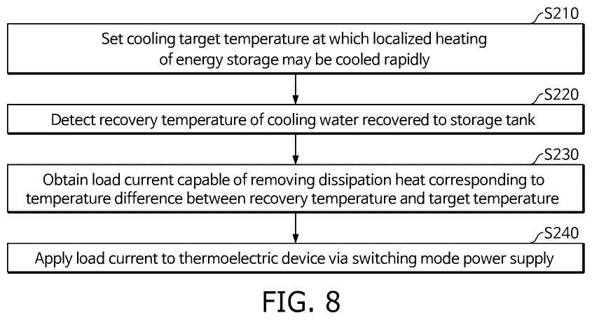

FIG. 8 illustrates a flowchart showing a method of driving the thermoelectric device 220 (FIG. 7 S200) according to some embodiments.

Referring to FIG. 8, first, the target temperature of the cooling water CW, at which the localized heating of the energy storage 700 may be cooled rapidly, is set (step S210).

The temperature setting portion 420 may detect information about overheating from the cooling signal and computationally determine the target temperature necessary for the rapid cooling of the overheated state. In another example, the target temperature may be any temperature set by a user who recognized the localized overheating based on a warning signal.

Thereafter, the recovery temperature of the cooling water CW recovered to the storage tank 110 is detected (step S220).

In response to receiving the cooling signal, the first driver 430 detects a recovery temperature, i.e., a temperature of the recovered hot cooling water HCW, by using the first sensor TS1. The first sensor TS1 may be disposed at the gate of the recovery pipe 120 to detect a temperature of the cooling water CW heated by the localized overheating of the energy storage 700 by detecting a temperature of the cooling water CW immediately after being discharged from the housing 600.

Thereafter, a load current capable of eliminating the amount of dissipation heat between the recovery temperature and the target temperature is obtained (step S230).

The first driver 430 obtains the temperature difference between the detected recovery temperature and the target temperature, and obtains the magnitude of a load current for dissipating an amount of heat of the cooling water CW corresponding to the temperature difference.

The load current may be computationally obtained based on the Peltier theory, taking into account the device characteristics of the thermoelectric device 220 and the properties of the cooling water CW. The load current is provided as a direct current (DC) for setting the cooling water CW to the target temperature by dissipating an amount of heat corresponding to the temperature difference from the cooling water CW.

Subsequently, the obtained load current is applied to the thermoelectric device 220 via a switching mode power supply (step S240).

The first driver 430 adjusts the switch-on time of the first power supply 240 operating in the switching mode so that the load current having the obtained magnitude is applied to the thermoelectric device 220.

AC power supplied to the first power supply 240 may be converted to DC power having a set intensity in response to the adjustment of the switch-on time. Accordingly, a load current having the magnitude obtained simply in response to the adjustment of the switch-on time may be applied to the thermoelectric device 220.

The thermoelectric device 220 may operate to cool the cooling plates 210 to cool the cooling water CW to the target temperature through the sidewalls of the storage tank 110 in contact with the cooling plates 210.

The cooling water CW cooled by the thermoelectric device 220 to a temperature lower than the recovery temperature is supplied to the housing 600 through the discharge pipe 130.

Returning to FIG. 7, in this case, the flow rate of the cooling water CW discharged from the storage tank 110 through the discharge pipe 130 may be controlled according to the discharge temperature (step S300).

The cooling water CW recovered at the recovery temperature is cooled by the thermoelectric device 220 to gradually reach the target temperature. However, during a transient period from the recovery temperature to reaching the target temperature, the cooling water CW supplied to the housing 600 may have a temperature higher than the target temperature, thereby making it difficult to rapidly cool the locally overheated energy cooler 700.

Accordingly, in a case where the cooling water CW that has not reached the target temperature is supplied to the housing 600, the flow rate of the cooling water CW may be increased to rapidly cool the overheated state.

Thereafter, the discharge flow rate of the cooling water CW discharged from the storage tank 110 may be controlled by the flow rate controller 300 according to the discharge temperature of the discharge temperature (step S300), thereby more rapidly eliminating the localized overheating of the energy storage 700.

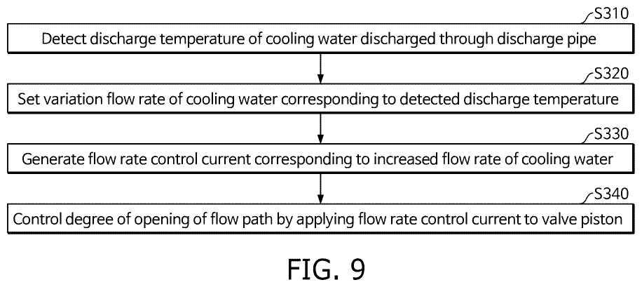

FIG. 9 illustrates a flowchart showing a method of controlling a discharge flow rate (FIG. 7 S300) according to some embodiments.

In the present embodiment, the flow rate controller 300 is implemented as an electronic proportional needle valve 322 configured to control the flow rate of the cooling water CW in proportion to applied power. Accordingly, a method of controlling a flow rate using a proportional needle valve 322 is disclosed.

However, this approach is illustrative, and the flow rate of the cooling water CW may be controlled by a variety of methods that may control the flow rate in proportion to the applied power according to alternate embodiments.

Referring to FIG. 9, first, a discharge temperature of the cooling water CW discharged from the storage tank 110 through the discharge pipe 130 may be detected (step S310).

In response to receiving the cooling signal, the second driver 440 periodically detects the discharge temperature of the cooling water CW flowing through the discharge pipe 130 by using the second sensor TS2. The second sensor TS2 is disposed at the outlet of the discharge pipe 130 to detect the temperature of the cooling water CW directly before being supplied to the housing 600, so that the detected temperature serves as a temperature of the cooling water CW supplied to cool the localized overheating of the energy storage 700.

Subsequently, a variation flow rate (or increase/decrease flow rate) of the cooling water CW may be set to correspond to the detected discharge temperature (step S320).

For example, the temperature difference between the target temperature and the discharge temperature may be obtained, and flow rates of the cooling water CW corresponding to respective temperature differences may be set in advance. In this manner, a difference between the present flow rate and the set flow rate may be set as the variation flow rate.

In an initial stage of the rapid cooling mode, a portion of the cooling water CW that has not reached the target temperature is discharged. Therefore, it is desired to increase the cooling water CW for cooling the localized overheating compared to the discharge flow rate of the state without localized overheating.

That is, in a case where cooling water CW having a temperature higher than the target temperature is supplied to the housing 600, the overheated cell may be cooled rapidly by increasing the discharge flow rate of the cooling water CW.

As the cooling water CW cools with the temperature thereof getting closer to the target temperature, a lower flow rate may be used to achieve the same cooling effect. Therefore, the localized overheating of the energy storage 700 may be cooled rapidly due to the lower cooling temperature of the cooling water CW even in a case where the cooling water CW is supplied in a smaller amount.

Accordingly, the variation flow rate of the cooling water CW may be set by empirically setting a flow rate of the cooling water CW supplied according to the temperature difference between the discharge temperature and the target temperature and comparing the set flow rate with the present discharge flow rate.

Thereafter, a flow rate control current corresponding to an increase in the flow rate of the cooling water CW may be generated (step S330).

In the present embodiment, the flow rate controller 300 may be implemented as an electronic proportional needle valve 322, which may control the flow rate in proportion of the applied power. Accordingly, a flow rate control current corresponding to the increased/decreased flow rate of the cooling water CW is generated.

The flow rate control current may be set arbitrarily depending on the characteristics between the flow rate and the current according to the device characteristics of the proportional needle valve 322.

In particular, in the present embodiment, the flow rate controller 300 is driven by the second power supply 340 generating a direct current in the switching mode, and thus the flow rate control current may be set simply by the setting of the switch-on time.

Subsequently, the degree of opening of the flow path 311 may be controlled by applying the flow rate control current to the valve piston 320 (step S340).

The stepper motor may be driven by applying the flow rate control current through the second power supply 340 operating in the switching mode, and the valve piston 320 coupled to the stepper motor may be moved linearly in the coupling opening 312. Consequently, the coupling position of the valve piston 320 may be moved linearly in the coupling opening 312.

Accordingly, the needle valve 322 disposed below the valve piston 320 is also moved linearly in the coupling direction so as to control the degree of opening between the needle valve 322 and the connecting hole H disposed on the flow path 311. Thus, the flow rate of the cooling water CW discharged through the flow path 311 may be controlled.

In particular, the degree of opening of the flow path 311 varies linearly depending on the magnitude of the flow rate control current applied to the valve piston 320, thereby causing the discharge flow rate of the cooling water CW to vary linearly depending on the flow rate control current.

Therefore, in a case where the discharge temperature is higher, the flow rate control current may be set to a higher value to increase the discharge flow rate. As the discharge temperature approaches the target temperature, the flow rate control current may be reduced to decrease the discharge flow rate. That is, the flow rate control current may be positively correlated with the discharge temperature to be set to a higher value for a higher discharge temperature.

At this time, the intensity of the flow rate control current applied to the stepper motor by the second power supply 340 may be changed simply by adjusting the switch-on time of the second power supply 340. Consequently, even in a case where the discharge flow rate of the cooling water CW varies depending on the discharge temperature, the discharge flow rate of the cooling water CW may be automatically adjusted by simply changing the flow rate control current.

According to the present embodiment described with reference to FIG. 9, the discharge flow rate is set differently depending on the temperature difference between the discharge temperature and the target temperature, but this is illustrative. The flow rate of the cooling water CW may be increased to a predetermined flow rate regardless of the target temperature of the cooling water CW according to alternate embodiments.

Returning to FIG. 7, thereafter, the cooling water CW with the set cooling temperature and discharge flow rate may be supplied to the inlet 610 of the housing 600 (step S400), thereby rapidly cooling the localized overheating of the energy storage 700.

The localized overheating occurring within the energy storage 700 may be cooled rapidly by supplying the cooling water CW, the target temperature of which is set to rapidly cool the localized overheating, at the discharge flow rate adjusted to increase the cooling efficiency.

Accordingly, overheating damage and fire in the energy storage system may be prevented by blocking heat transfer from the locally overheated cell to adjacent unit cells.

According to the cooling apparatus described according to various embodiments, the energy storage system including the same, and the method of cooling an energy storage system using the same as described above, in a case where localized overheating occurs in the energy storage during operation, the overheated state may be detected in advance and the cooling apparatus may be controlled in advance to rapidly cool the localized heating, thereby preventing the localized overheating from causing damage, failure, or fire to the energy storage cells.

The overheated cell may be rapidly cooled by transmitting the localized overheated state on the cooling signal to the cooling apparatus, cooling the cooling water to a target temperature, and supplying the cooling water at an increased flow rate to the energy storage.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. A cooling apparatus comprising:
a cooling water flow device comprising a recovery pipe through which cooling water is configured to be recovered to a storage tank and a discharge pipe through which the cooling water is configured to be discharged from the storage tank;
a temperature controller disposed on the storage tank and configured to control a temperature of the cooling water stored in the storage tank based on a load current applied thereto;
a flow rate controller disposed on the discharge pipe of the cooling water and configured to control a discharge flow rate of the cooling water based on a flow rate control current; and
a cooling controller configured to control the discharge flow rate and a cooling temperature of the cooling water together by driving the flow rate controller and the temperature controller in response to a cooling signal.

2. The cooling apparatus as claimed in claim 1, wherein the temperature controller comprises:
a cooling plate configured to cover an outer surface of the storage tank;
a plurality of thermoelectric devices, each comprising a top portion in contact with a bottom portion of the cooling plate and configured to cool the cooling water by Peltier effect via the cooling plate; and
a heat dissipation plate in contact with bottom portions of the plurality of thermoelectric devices to dissipate heat absorbed from the cooling water.

3. The cooling apparatus as claimed in claim 2, wherein each of the plurality of thermoelectric devices comprises:
a pair of semiconductor elements having different polarities;
individual conductors provided as electrodes in contact with the pair of semiconductor elements, respectively; and
a bridge conductor in simultaneous contact with the pair of semiconductor elements to be provided as a bridge electrode, and in contact with the cooling plate.

4. The cooling apparatus as claimed in claim 3, wherein the pair of semiconductor elements comprises p-type and n-type semiconductors connected in series and comprises bismuth telluride (Bi2Te3) or lead telluride (PbTe).

5. The cooling apparatus as claimed in claim 3, wherein each of the individual conductors comprises a copper plate.

6. The cooling apparatus as claimed in claim 2, wherein the temperature controller further comprises a first power supply configured to generate a direct current in a switching mode.

7. The cooling apparatus as claimed in claim 1, wherein the flow rate controller comprises an electric flow rate control valve configured to control the discharge flow rate of the cooling water in proportion to the flow rate control current.

8. The cooling apparatus as claimed in claim 7, wherein the flow rate controller comprises:
a valve spool comprising a flow path configured to be connected to the discharge pipe in a flow direction of the cooling water, the flow path being selectively connected by means of a connecting hole, and a coupling opening connected to the flow path and extending in a coupling direction different from the flow path;
a valve piston inserted in and rotatably coupled to the coupling opening, and configured to move linearly in the coupling direction by rotational movement in the coupling opening, thereby changing an open area of the connecting hole;
a drive unit configured to drive the valve piston; and
a second power supply configured to supply the flow rate control current as a direct current to the drive unit.

9. The cooling apparatus as claimed in claim 1, wherein the cooling controller comprises:
a temperature setting portion configured to set a target temperature for the cooling water;
a first driver configured to drive the temperature controller so that a recovery temperature of the cooling water is equal to the target temperature;
a second driver configured to drive the flow rate controller to control the discharge flow rate of the cooling water; and
a cooling processor configured to set operating states of the temperature controller and the flow rate controller by comparing a discharge temperature of the cooling water and the target temperature.

10. The cooling apparatus as claimed in claim 9, wherein the recovery pipe comprises a first temperature sensor disposed at an inlet to detect the recovery temperature of the cooling water entering the storage tank, and
the discharge pipe comprises a second temperature sensor disposed at an outlet to detect the discharge temperature of the cooling water discharged from the storage tank.

11. An energy storage system comprising:
a housing configured to comprise a flow path through which cooling water flows;
an energy storage configured to comprise a plurality of energy storage cells arranged within the housing to store electrical energy and configured to be cooled with the cooling water;
a cell control center configured to detect operating states of the energy storage cells by simultaneous contact therewith and to transmit a cooling signal for rapidly cooling a detected overheated cell among the plurality of energy storage cells; and
a cooling apparatus configured to circulate the cooling water within the housing to cool the energy storage and simultaneously control a cooling temperature and a discharge flow rate of the cooling water in response to the cooling signal.

12. The energy storage system as claimed in claim 11, wherein the housing comprises an inlet through which the cooling water enters, an outlet through which the cooling water is discharged, and flow guides configured to guide the cooling water to the energy storage cells.

13. The energy storage system as claimed in claim 12, wherein the cooling apparatus comprises:
a cooling water flow device comprising a recovery pipe configured to be connected to the outlet and allow cooling water to be recovered to a storage tank therethrough and a discharge pipe configured to be connected to the inlet and allow the cooling water to be discharged from the storage tank to the housing;
a temperature controller disposed on the storage tank to control a temperature of the cooling water stored in the storage tank by means of a load current applied thereto;
a flow rate controller disposed between the discharge pipe and the storage tank to control the discharge flow rate of the cooling water by means of a flow rate control current; and
a cooling controller configured to control the discharge flow rate and the cooling temperature of the cooling water together by driving the flow rate controller and the temperature controller in response to a cooling signal.

14. The energy storage system as claimed in claim 13, wherein each of the cell control center and the cooling controller is configured to communicate cooling information via wired communication or wireless communication.

15. The energy storage system as claimed in claim 13, wherein the cooling controller comprises:
a temperature setting device configured to set a target temperature;
a first driver configured to drive the temperature controller so that a recovery temperature of the cooling water is equal to the target temperature;
a second driver configured to drive the flow rate controller to control the discharge flow rate of the cooling water; and
a cooling processor configured to control operations of the first driver and the second driver by comparing a discharge temperature of the cooling water and the target temperature.

16. A method of cooling an energy storage system, the method comprising:
receiving a cooling signal for rapidly cooling localized overheating from a cell control center of energy storage cells cooled with cooling water;
driving thermoelectric devices to reduce a temperature of cooling water, recovered from a housing, to a target temperature for the rapid cooling;
controlling a discharge flow rate of the cooling water according to a discharge temperature of the cooling water discharged from the storage tank; and
supplying the cooling water to the housing, wherein the cooling temperature and the discharge flow rate of the cooling water are controlled.

17. The method as claimed in claim 16, wherein the driving the thermoelectric devices comprises:
setting the target temperature of the cooling water;
detecting a recovery temperature of the cooling water recovered to the storage tank;
obtaining a load current capable of removing an amount of dissipation heat between the recovery temperature and the target temperature; and
applying the load current as a direct current to the thermoelectric devices.

18. The method as claimed in claim 17, where an intensity of the load current is controlled by adjusting a switch-on time of a switching mode power supply.

19. The method as claimed in claim 18, wherein the controlling the discharge flow rate comprises:
detecting the discharge temperature of the cooling water discharged the storage tank;
setting a variation flow rate corresponding to the discharge temperature;
generating a flow rate control current corresponding to the variation flow rate; and
adjusting an open area of a flow path through which the cooling water flows by applying the flow rate control current to a valve piston.

20. The method as claimed in claim 19, wherein the flow rate control current is positively correlated with the discharge temperature so that the flow rate control current is controlled to increase with increases in the discharge temperature.
